(19) United States
(12) Patent Application Publication
(10) Pub. No.: US 2005/0237231 A1
(43) Pub. Date: Oct. 27, 2005

(54) System and method for data synchronization

(75) Inventor: Chung-Wen Liao, Taichung City (TW)

Correspondence Address: LADAS & PARRY, 26 WEST 61ST STREET, NEW YORK, NY, 10023, US

(73) Assignee: BENQ CORPORATION

(21) Appl. No.: 11/093,314

(22) Filed: Mar. 30, 2005

(30) Foreign Application Priority Data
Apr. 2, 2004 (TW) 93109228

(51) Int. Cl. H03M 5/00

(52) U.S. Cl. 341/52

(57) ABSTRACT

A system and method is used to form a data packet for data synchronization. The data packet comprises a recognizing data and a content data. The recognizing data comprises a guard data and a pattern data. The system and method predetermines bits number of the pattern data, and permutes a plurality of recognizing data sets according to the bits number. Subsequently, the system and method transforms these recognizing data sets to a plurality of counting data sets using the bit mapping procedure. The system and method calculates a plurality of contrast parameter based on these counting data using the half-autocorrelation procedure, and chooses a chosen recognizing data having the smallest. contrast parameter. Finally, the system and method combines the chosen recognizing data and the content data to generate the data packet.

### BACKGROUND OF THE INVENTION

(1) Field of the Invention

The invention relates to a system and method for data synchronization, and more particularly to a system and method for synchronizing data between circuit boards.

(2) Description of the Prior Art

Refer to FIG. 1 for a conventional technique for data transmission. A circuit board serving as a transferring end 2 is linked to another circuit board which serves as a receiving end 4 through a signal line 6 for transmitting a data string from the transferring end 2 to the receiving end 4. In order to enable the transferring end 2 and the receiving end 4 to recognize the data the same way, namely to synchronize the data at the two ends 2 and 4. The data are transmitted through data packets so that the receiving end 4 can recognize the content of the received data.

Refer to FIG. 2 for a data string 8 transmitted by the conventional technique. It includes data packets 10 each has a recognizing data 12 and a content data 14. The recognizing data 12 includes a guard data 12a and a pattern data 12b. All of the data mentioned above consist of “1” and “0”.

The content data 14 may be program codes, digital data, image data, or audio data. It is the main information to be transmitted between the transferring end 2 and the receiving end 4. The recognizing data 12 serves the beginning of the content data 14 in the data string 8. When the receiving end 4 receives the data string 8 and recognizes the recognizing data 12, it treats the follow on data string 8 as the content data 14 and processes accordingly.

However, errors could occur while the receiving end 4 identifies the recognizing data 12. For instance, if the recognizing data 12 is 00001, when the content data 14 also contains 00001, it could be treated mistakenly as the recognizing data 12. This mistaken recognizing may be reduced by increasing the bit number of the recognizing data 12, such as change the previous recognizing data 12 that contains five bits of 00001 to nine bits of 000000001. However, such an approach increases the overhead of data transmission and reduces data transmission efficiency. Moreover, the length of the recognizing data at the transferring end and the receiving end usually are fixed in the same system. For data that is more important or a circuit transmission path that has a longer link, to adjust the length and content of the recognizing data 12 is not flexible.

### SUMMARY OF THE INVENTION

Therefore it is an object of the present invention to provide a more efficient system and method of data synchronization to overcome the aforesaid problems by adjusting the length and content of the recognizing data.

In one aspect, the present invention aims to provide a system and method for data synchronization to reduce the probability of mistaken recognition of the recognizing data without increasing the bit number thereof so that the transmission efficiency of the content data may be improved.

The system and method for data synchronization according to the present invention is adaptable for transmitting data strings from a transferring end to a receiving end through a data packet. The data packet includes a recognizing data and a content data. The recognizing data includes a guard data and a pattern data. The content data has a selected length, and may be program codes, digital data, image data, or audio data.

The method of the present invention includes the following procedure: first, select the bit number of the pattern data; next, generate a plurality of recognizing data sets according to the guard data and the bit number corresponding to the pattern data.

Transform the recognizing data sets to a plurality of counting data sets through a bit mapping procedure. Derive a plurality of contrast parameters from the counting data sets through a half-autocorrelation procedure.

Select a chosen recognizing data among the recognizing data sets that has the smallest contrast parameter. Finally combine the chosen recognizing data and the content data to form the data packet.

The receiving end compares the chosen recognizing data that has the smallest contrast number with the received transmission data string. When the received transmission data string has data matching the recognizing data, the follow on transmitting data string of a selected length is treated as the content data.

Thus the invention provides a more efficient system and method for data synchronization that uses bit mapping and half-autocorrelation to generate corresponding contrast parameters for all recognizing data and selects the recognizing data with the smallest contrast parameter without increasing the bit number of the recognizing data to reduce the probability of mistaken recognition of the recognizing data. Thereby recognizing accuracy of the content data improves and transmission efficiency of the content data increases.

### BRIEF DESCRIPTION OF THE DRAWINGS

The present invention will now be specified with reference to its preferred embodiments illustrated in the drawings, in which

FIG. 1 is a schematic view of a conventional data transmission technique;

FIG. 2 is a schematic view of a transmission data string that adopts a conventional technique;

FIG. 3 is a schematic view of the data synchronization system of the invention;

FIG. 4 is a schematic view of a receiving end of the invention;

FIG. 5 is a schematic view of pattern candidate generating of the invention;

FIG. 6 is a schematic view of the bit mapping module of the invention in a mapping process;

FIG. 7 is a schematic view of the processing module of the invention in a half-autocorrelation process;

FIG. 8 is a table showing error probability relationship between the recognizing data and the contrast parameters; and

FIG. 9 is a flow chart of the data synchronization method of the invention.

### DESCRIPTION OF THE PREFERRED EMBODIMENTS

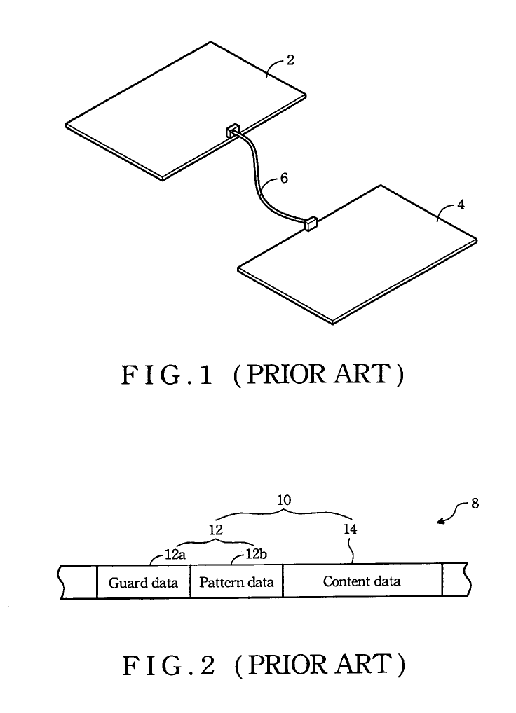

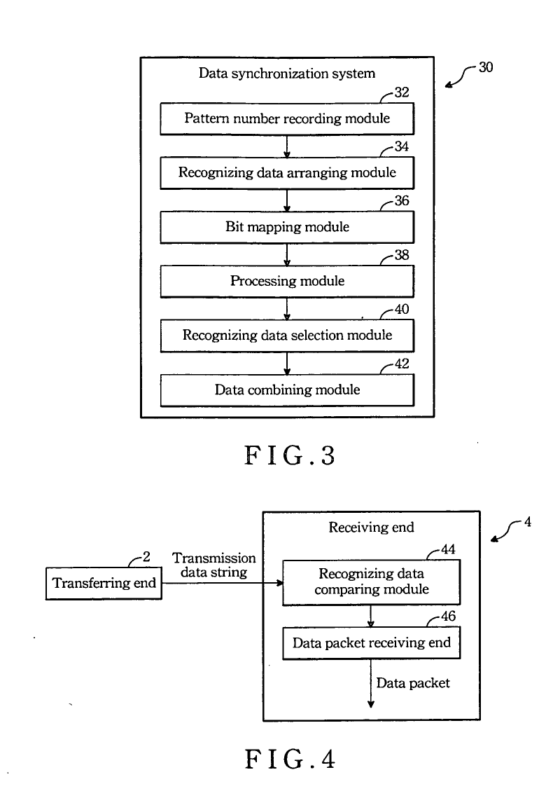

Refer to FIG. 3 for a data synchronization system 30 according to the invention. As shown in FIG. 1, it aims to form a data packet during transmission of a data string from a transferring end to a receiving end. The transferring end and the receiving end may be two circuit boards. As shown in FIG. 2, the data packet includes a recognizing data and a content data. The content data has a selected length. The recognizing data includes a guard data and a pattern data. The content data may be program codes, digital data, image data, or audio data.

Referring to FIG. 3, the data synchronization system 30 includes a pattern number recording module 32, a recognizing data arranging module 34, a bit mapping module 36, a processing module 38, a recognizing data selection module 40 and a data combining module 42.

The pattern number recording module 32 aims to register the bit number of the pattern data. The recording bit number is jointly determined by the transferring end and the receiving end. In general, the guard data has a fixed number of bits. But it may be changed through the pattern number recording module 32.

The bit number of the pattern number is determined by the content data. In principle, more important content data are given more bit number of the pattern number. In practice, automatic determination may be made according to the bit number of the content data. When the bit number of the content data increases, the bit number of the corresponding pattern data also increases. Another approach is to treat the program codes and digital data as important content data, while the image data and audio data as less important content data. The important data are given more bit number of the pattern number.

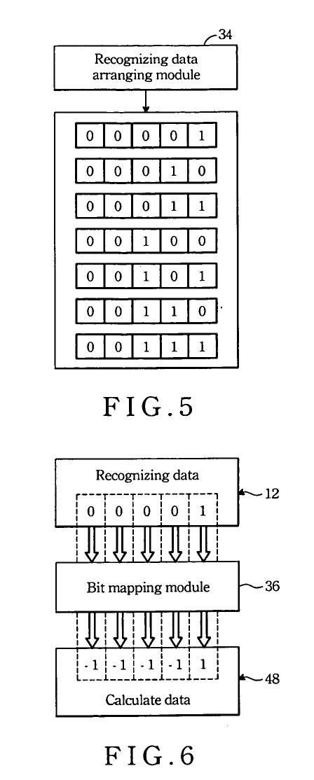

The recognizing data arranging module 34 generates a plurality of recognizing data sets according to the guard data and the bit number corresponding to the pattern data, and arranges the recognizing data sets. More details will be discussed later accompanying FIG. 5

The bit mapping module 36 transforms the recognizing data sets to a plurality of counting data sets through a bit mapping procedure. Details will be discussed later accompanying FIG. 6.

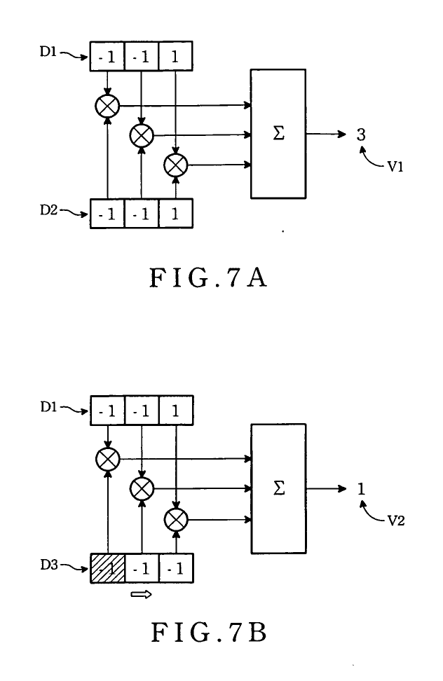

The processing module 38 processes the counting data sets through a half-autocorrelation procedure to derive a plurality of corresponding contrast parameters. Details of the half-autocorrelation procedure will be discussed later accompanying FIG. 7.

The recognizing data selection module 40 aims to select a chosen recognizing data among the recognizing data sets that has the smallest contrast parameter. The recognizing data arranging module 34 has arranged the sequence of all recognizing data according to a selected sequencing principle to allow the transferring end and the receiving end to produce the same sequence. When the recognizing data selection module 40 recognizes there are two or more equal smallest contrast parameters, the recognizing data with the smallest contrast parameter that is sequenced first is chosen.

Finally, the data combining module 42 combines the chosen recognizing data and the content data to form the data packet for the transferring end to transmit to the receiving end, and to enable both ends to perform recognition and synchronization processes.

In practice, the transferring end and the receiving end can include the recognizing data arranging module 34, bit mapping module 36, processing module 38, and recognizing data selection module 40 so that the receiving end can generate the data packet while the receiving end can recognize the data packet. The pattern number recording module 32 may be located respectively in the transferring end and the receiving end, or externally connected to the transferring end and the receiving end to facilitate defining the bit number of the pattern data in a coincided manner. The data combining module 42 functions only in the transferring end.

Refer to FIG. 4 for a receiving end 4 of the invention. In the data synchronization system 30, the receiving end 4 receives the data packet. The receiving end 4 includes a recognizing data comparing module 44 and a data packet receiving module 46.

The recognizing data comparing module 44 aims to compare the chosen recognizing data of the smallest contrast parameter with the transmitting data string received from the transferring end 2. When the received transmitting data string matches the recognizing data, the data packet receiving module 46 treats the follow on transmitting data string as the content data to achieve synchronization of the content data.

Refer to FIG. 5 for pattern candidate generating of the invention. The recognizing data arranging module 34 arranges every combination of all guard data and pattern data in a sequence from small to large. For instance, if the bit number of the guard data is 2, and the bit number of the pattern number is 3, with the guard data generally represented by 0, the pattern data has seven different layouts as shown in FIG. 5, in the sequence of (0,0,0,0,1), (0,0,0,1,0), (0,0,0,1,1), (0,0,1,0,0), (0,0,1,0,1), (0,0,1,1,0) and (0,0,1,1,1). The combination of (0,0,0,0,0) has a greater chance of producing errors, thus is eliminated.

Referring to FIG. 6 for the bit mapping module 36 of the invention in a mapping process. In the data synchronization system 30, the recognizing data 12 consists of “1” and “0”. The bit mapping process is to transform the recognizing data 12 of “1” and “0” to corresponding “1” and “−1” of a counting data 48 through the bit mapping module 36. As shown in FIG. 6, the recognizing data 12 originally consists of (0,0,0,0,1), after transformed by the bit mapping module 36, it becomes the counting data 48 consisting of (−1,−1,−1,−1,1).

Refer to FIGS. 7A and 7B for the half-autocorrelation process performed by the processing module 38. In the data synchronization system 30, the half-autocorrelation process includes the following procedure:

Referring to FIG. 7A, the example of the counting data shown in FIG. 6 is (−1,−1,−1,−1,1). However, in practice, the original guard data is represented by (0,0), hence it may be not included in the half-autocorrelation process, and only the pattern data (0,0,1) is included in the process. Thus the actual counting data to be used is (−1,−1,1).

First, replicate the counting data (−1,−1,1) to become a first counting data (−1,−1,1) D1 and a second counting data (−1,−1,1) D2. Multiply the corresponding bits at the same position of the first counting data D1 and the second counting data D2 and sum up a first counting value V1. In FIG. 7A, the counting value is 3.

Referring to FIG. 7B, the second counting data is shifted by one bit, and the vacant area is filled with “−1” to become a new second counting data (−1,−1,−1) D3, then multiply the corresponding bits at the same position of the first counting data D1 and the new second counting data D3 and sum up a second counting value V2. In FIG. 7B, the second counting value is 1.

Repeat the processes depicted in FIGS. 7A and 7B until the shifting times equals to the bit number of the first counting data. In the embodiment shown in FIG. 7, total shifting times is four. The resulting counting values V1, V2, V3, V4 are respectively 3, 1, 1, 1. Next, sum up the counting values of V1, V2, V3, V4 to become the contrast parameter. In the embodiment of FIG. 7, the contrast parameter is 6.

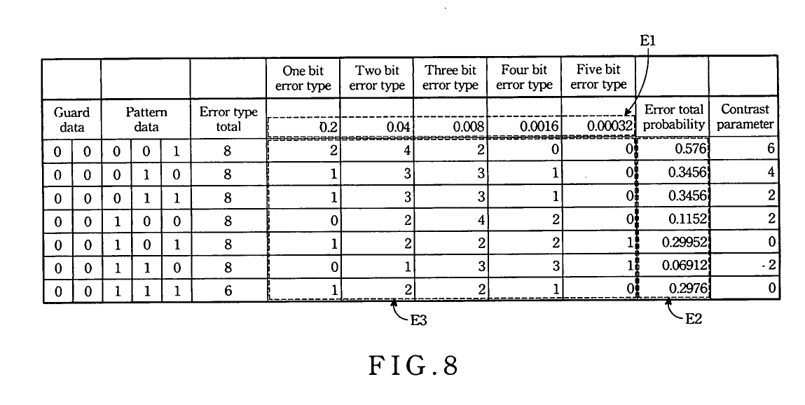

Next, all of the recognizing data arranged by the recognizing data arranging module 34 in the pattern candidate generating shown in FIG. 5 are processed by the method depicted in FIG. 7 to get the contrast parameters. Total seven contrast parameters are obtained, i.e. 6, 4, 2, 2, 0, −2, and 0. Refer to FIG. 8 for more descriptions of the seven contrast parameters

Refer to FIG. 8 for the error probability relationship between the recognizing data and the contrast parameters. The row E1 contains preset parameters of error probability. The frame E3 contains the number of error types corresponding to the bit number on the upper side and the recognizing data on the left side. For instance, the probability of occurring error types in the number of two bits for the recognizing data (0,0,0,0,1) is four. Multiply the error probability parameter E1 on the upper side and the error type number E3, total error probability E2 of the recognizing data is shown on the right column. For instance, the total error probability of the recognizing data (0,0,0,0,1) is 0.576. Thus it proves that the smaller the contrast number of the recognizing data, the smaller the error probability becomes. As shown in FIG. 8, the sixth recognizing data (0,0,1,1,0) has the smallest error probability (0.06912). It also has the smallest contrast parameter (−2).

In data synchronization system 30, the pattern number recording module 32, recognizing data arranging module 34, bit mapping module 36, processing module 38, recognizing data selection module 40, data combining module 42 and recognizing data comparing module 44 may be application programs (AP) written by C language or assembly language, and stored in the memory (such as ROM or Flash memory). They may be executed in a desired processor (such as a Digital Signal Processor—DSP or Micro Controller Unit—MCU) to perform required functions. They also may be written by Verilog or VHDL language, and compiled and stored in a Complex Programmable Logic Device (CPLD) or FPGA to perform the required functions.

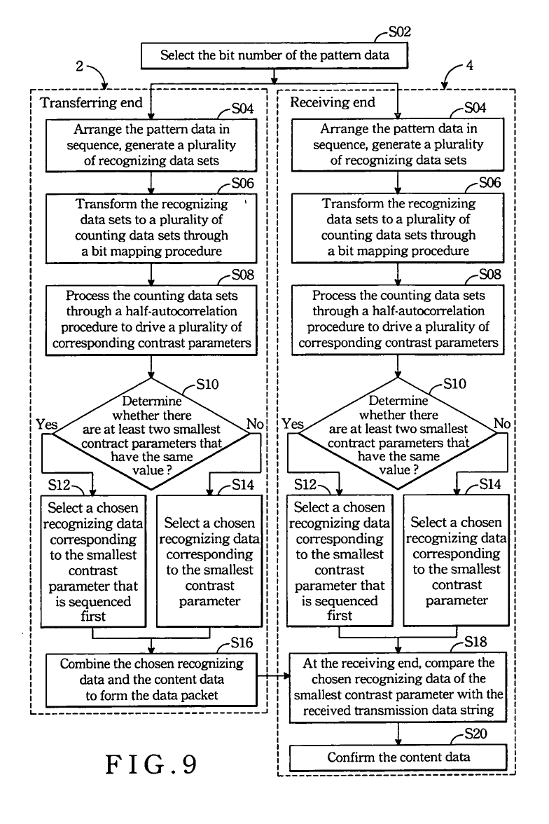

The data synchronization system 30 previously discussed also elaborates the method of the invention. Refer to FIG. 9 for the process flow of the data synchronization method of the invention adopted for use on the transferring end 2 and the receiving end 4. It includes the following procedure:

Step S02: First, select a bit number of the pattern data, same for the transferring end 2 and the receiving end 4.

Step S04: Generate a plurality of recognizing data sets according to the guard data and the bit number corresponding to the pattern data, and according to a sequence arranged by a selected sequencing principle (such as a numeric number from small to large, i.e. 0 is ahead 1). This step may also be called pattern candidate generating, and must be performed on the transferring end 2 and the receiving end 4 so that they generate the same sequence.

Step S06: Transform the recognizing data sets to a plurality of counting data sets through a bit mapping procedure. This step may be performed respectively at the transferring end 2 and the receiving end 4, and the counting data sets are same at both ends.

Step S08: Process the counting data sets through a half-autocorrelation procedure to derive a plurality of corresponding contrast parameters. This step may be performed respectively at the transferring end 2 and the receiving end 4.

Step S10: Determine whether there are at least two smallest contract parameters of the same value in the recognizing data. This step may be performed respectively at the transferring end 2 and the receiving end 4.

Step S12: If the outcome of Step S10 is positive, select a chosen recognizing data corresponding to the smallest contrast parameter that is sequenced first as the chosen recognizing data. This step may be performed respectively at the transferring end 2 and the receiving end 4.

Step S14: If the outcome of Step S10 is negative, select a chosen recognizing data corresponding to the smallest contrast parameter as the chosen recognizing data. This step may be performed respectively at the transferring end 2 and the receiving end 4.

Step S16: At the transferring end 2, combine the chosen recognizing data and the content data to form the data packet.

Step S18: At the receiving end 4, compare the chosen recognizing data of the smallest contrast parameter with the transmission data string received from the transferring end 2.

Step S20: At the receiving end 4, receive the transmission data string sequentially. When the transmission data string has data same as the recognizing data, a selected length of the follow on data of the transmission data string is treated as the content data.

Thus the data synchronization system 30 and the method thereof is more efficient. Through the bit mapping procedure and the half-autocorrelation process, corresponding contrast parameters may be generated for all recognizing data, and the recognizing data of the smaller contrast parameter may be chosen without increasing the bit number of the recognizing data to reduce error probability of mistaken recognition of the recognizing data. The probability of accurate recognition of the content data improves, and the transmission efficiency of the content data also increases.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

1. A method for data synchronization to generate a data packet which contains a recognizing data and a content data, the recognizing data including a guard data and a pattern data, the method comprising the steps of:
selecting a bit number for the pattern data;
generating a plurality of recognizing data sets according to the guard data and the bit number;
transform the recognizing data sets to a plurality of counting data sets through a bit mapping procedure;
processing the counting data sets through a half-autocorrelation procedure to derive a plurality of contrast parameters;
selecting a chosen recognizing data having a smallest contrast parameter from the recognizing data sets; and
combining the chosen recognizing data and the content data to from the data packet.

2. The method of claim 1, a transmission data string transmitting from a transferring end to a receiving end, the transmission data string including the data packet, the content data having a selected length, the method further comprising:
comparing the chosen recognizing data with a smallest contrast parameter to the transmission data string at the receiving end; and
setting a selected length of data of the sequentially received transmission data string following a data set thereof as the content data when the data set matches the chosen recognizing data.

3. The method of claim 2, wherein the transferring end and the receiving end are respectively a circuit board.

4. The method of claim 1, wherein the bit number corresponding to the pattern data corresponds to the bit number of the content data.

5. The method of claim 4, wherein the corresponding bit number of the pattern data increases as the bit number of the content data increases.

6. The method of claim 1, wherein the method is used to transmit data from a transferring end to a receiving end, the bit number of the pattern data is determined jointly by the transferring end and the receiving end.

7. The method of claim 6, wherein the bit number of the pattern data increases when the data transmitted by the transferring end and the receiving end is an important data.

8. The method of claim 6, wherein the bit number of the pattern data increases when the data transmitted by the transferring end is selected from the group consisting of program codes and digital data.

9. The method of claim 2, wherein all of the recognizing data are sequenced according to a selected sequencing principle such that the transferring end and the receiving end arrange the data at the same sequence.

10. The method of claim 9, wherein the recognizing data sequenced first is chosen when at least two of the recognizing data have the same summation of contrast parameters.

11. The method of claim 1, wherein the recognizing data consists of “1” and “0” and the bit mapping procedure corresponds the “1” and “0” respectively to “1” and “−1” of the counting data.

12. The method of claim 1, wherein the processing the counting data sets through a half-autocorrelation procedure includes the steps of:
step A: replicating one counting data to a first counting data and a second counting data;
step B: multiplying the corresponding bits of the first counting data and the second counting data of the same locations and adding total of the multiplication to become a counting value;
step C: shifting the second counting data by one bit and filling the vacant area by “−1” as the second counting data;
step D: repeating steps B and C until shifting times being same as the bit number of the first counting data; and
step E: summing counting values generated by step B as the contrast parameter.

13. A data synchronization system to generate a data packet which contains a recognizing data and a content data, the recognizing data including a guard data and a pattern data, the system comprising:
a pattern number recording module for inputting a bit number of the pattern data;
a recognizing data arranging module to generate a plurality of recognizing data sets according to the guard data and the bit number corresponding to the pattern data;
a bit mapping module to transform the recognizing data sets to a plurality of counting data sets through a bit mapping procedure;
a processing module to process the counting data sets through a half-autocorrelation procedure to derive a plurality of contrast parameters;
a recognizing data selection module to select a chosen recognizing data among the recognizing data sets that has the smallest contrast parameter; and
a data combining module to combine the chosen recognizing data and the content data to form the data packet.

14. The data synchronization system of claim 13, wherein a transferring end transmits a transmission data string to a receiving end, the transmission data string including the data packet, the content data having a selected length, the receiving end further comprising:
a recognizing data comparing module to compare the chosen recognizing data of the smallest contrast parameter with the received transmission data string; and
a data packet receiving module to receive the transmission data string sequentially and treat the transmission data string following a data set thereof as the content data when the data set matches the chosen recognizing data.

15. The data synchronization system of claim 14, wherein the transferring end and the receiving end are respectively a circuit board.

16. The data synchronization system of claim 13, wherein the bit number corresponding to the pattern data corresponds to the bit number of the content data.

17. The data synchronization system of claim 16, wherein the corresponding bit number of the pattern data increases as the bit number of the content data increases.

18. The data synchronization system of claim 13, wherein the system is used to transmit data from a transferring end to a receiving end, the bit number of the pattern data is determined jointly by the transferring end and the receiving end.

19. The data synchronization system of claim 18, wherein the bit number of the pattern data increases when the data transmitted by the transferring end and the receiving end is an important data.

20. The data synchronization system of claim 19, wherein the important data is selected from the group consisting of program codes and digital data.

21. The data synchronization system of claim 14, wherein all of the recognizing data are sequenced according to a selected sequencing principle such that the transferring end and the receiving end arrange the data at the same sequence.

22. The data synchronization system of claim 21, wherein the recognizing data sequenced first is chosen when at least two of the recognizing data have the same contrast parameter.

23. The data synchronization system of claim 13, wherein the recognizing data consists of “1” and “0” and the bit mapping module corresponds the “1” and “0” respectively to “1” and “−1” of the counting data.

24. The data synchronization system of claim 13, wherein the to process the counting data sets through a half-autocorrelation procedure includes the steps of:
A: replicating one counting data to become a first counting data and a second counting data;
B: multiplying the corresponding bits of the first counting data and the second counting data of the same locations and adding total of the multiplication to become a counting value;
C: shifting the second counting data by one bit and filling the vacant area by “−1” as the second counting data;
D: repeating steps B and C until shifting times being same as the bit number of the first counting data; and
E: summing the counting values generated by step B as the contrast parameter.
